(19) United States
(12) Patent Application Publication
(10) Pub. No.: US 2020/0116776 A1
(43) Pub. Date: Apr. 16, 2020

(54) Device for Detecting a Short Circuit, Protection Device and Associated Method for a High-Voltage Dc Network

(71) Applicant: Supergrid Institute, Villeurbanne (FR)

(72) Inventors: Boussaad Ismail, Lyon (FR); Eric Courbon, Lyon (FR); Alessandro Tundo, Lyon (FR); Ludovic Boyer, Lyon (GB); Serge Poulain, Lyon (FR); Alberto Bertinato, Lyon (FR); Fabrizio Callari, Lyon (FR)

(21) Appl. No.: 16/618,961

(22) PCT Filed: Jun. 4, 2018
(86) PCT No.: PCT/EP2018/064576

§ 371 Date: Dec. 3, 2019

(30) Foreign Application Priority Data
Jun. 6, 2017 (FR) 1754987

(51) Int. Cl. G01R 31/08; G01R 31/28; H04B 3/54; H01B 7/32; G02B 6/44; H02H 7/26

(52) U.S. Cl. CPC G01R 31/085; G01R 31/2812; H02H 7/268; H01B 7/32; G02B 6/4417; H04B 3/548

(57) ABSTRACT

A detection device for detecting a short circuit current in an electrical power transmission cable having an electrical power transmission cable for a high-voltage DC network. The network includes a central core, an insulating sheath, a metal screen arranged around the insulating sheath, at least one optical fibre, arranged between the electrically conductive central core and the metal screen by forming windings around the central core in a detection region, two optical transmitters arranged at the ends of the electrical power transmission cable, two optical detectors arranged at ends of the electrical power transmission cable, two interruption devices arranged at the ends of the electrical power transmission cable when a change in the angle of polarisation with respect to a reference angle greater than a predetermined value is detected by the first optical detector.

The field of the present invention relates to the transmission of electricity in high-voltage direct-current (HVDC) networks and more particularly to a device for protecting an HVDC cable from short circuits, and to associated detection and protection methods allowing a fault to be detected in the said electrical power transmission cable and it to be powered down.

The current development of renewable energies creates new pressures in the electricity network as the different electricity production facilities are generally located at a distance from each other and from consumption zones. It thus appears necessary to develop new transmission networks able to transmit electricity over very long distances while minimizing energy losses.

To respond to these constraints, high-voltage (for example 320 kV) direct-current (HVDC) networks appear to be a promising solution due to lower line losses than on alternating current networks and the absence of the incidence of stray capacitances on the network over long distances.

However, in such HVDC networks, in particular in multi-point or multi-node networks, in the event of a short circuit on one of the lines, the fault propagates very quickly throughout the entire system and the short-circuit current can reach several tens of kA in a few milliseconds and exceed the tripping capacity of HVDC circuit-breakers which is generally limited to approximately 15 kA.

A reliable and fast protection strategy should therefore be established, to detect a fault, to localize it and to switch the faulty line locally to prevent its propagation to the rest of the network and also to avoid powering-down a large part of the network.

To this end, the present invention relates to a device for detecting a short-circuit current in an electrical power transmission cable, comprising:

an electrical power transmission cable for a high-voltage direct-current network, comprising:
an electrically conductive central core configured to transmit an electrical current,
an electrically insulating jacket arranged around the central core,
a metal screen arranged around the insulating jacket,

and wherein the electrical power transmission cable also comprises at least one optical fiber extending along the electrical power transmission cable, in which cable, in at least one detection zone of the electrical power transmission cable, the said optical fiber is arranged between the electrically conductive central core and the metal screen and forms windings around the central core,

a first optical transmitter arranged at a first end of the electrical power transmission cable and configured to transmit an optical signal in an optical fiber of the said electrical power transmission cable,

a second optical transmitter arranged at a second end of the electrical power transmission cable and configured to transmit an optical signal in an optical fiber of the said electrical power transmission cable,

a first optical detector arranged at the first end of the electrical power transmission cable and configured to detect a change in the polarization angle of the optical signal transmitted by the second optical transmitter and associated with a fault signal,

a first switching device arranged at the first end of the electrical power transmission cable, coupled to the first optical detector and configured to switch the connection of the electrical power transmission cable when a change in the polarization angle, relative to a reference angle, greater than a predetermined value is detected by the first optical detector,

a second optical detector arranged at the second end of the electrical power transmission cable and configured to detect a change in the polarization angle of the optical signal transmitted by the first optical transmitter and associated with a fault signal,

a second switching device arranged at the second end of the electrical power transmission cable, coupled to the second optical detector and configured to switch the connection of the electrical power transmission cable when a change in the polarization angle, relative to a reference angle, greater than a predetermined value is detected by the second optical detector.

The device according to the invention, by having two detectors, one at each end of the cable, enables a short circuit to be detected more quickly by the Faraday effect, and thus increases the chances of cutting off the power supply to the cable before the propagation of the cable beyond the said cable.

The device according to the invention may also have one or more of the following features, individually or in combination.

The first or the second switching device respectively can also be configured to switch the connection of the electrical power transmission cable in the absence of receipt of an optical signal by the first optical detector or by the second optical detector respectively.

The first optical transmitter can be configured to transmit a signal at a first wavelength, and the second optical transmitter is configured to transmit a signal at a second wavelength different from the first wavelength.

The device may also comprise:

a first current detector arranged at the first end of the electrical power transmission cable and configured to detect an electrical fault signal transmitted by the electrical power transmission cable,

a first processing unit arranged at the first end of the electrical power transmission cable and coupled to the first optical detector and to the first current detector, and configured to determine, on the one hand, a direction of the electrical fault signal received and, on the other hand, the time lag between the time of receipt of the electrical fault signal and the time of receipt of the optical fault signal, and to localize a fault zone from the direction of the electrical fault signal and the time of receipt of the optical and electrical fault signals,

a second current detector arranged at the second end of the electrical power transmission cable and configured to detect an electrical fault signal transmitted by the electrical power transmission cable,

a second processing unit arranged at the second end of the electrical power transmission cable and coupled to the second optical detector and to the second current detector, and configured to determine, on the one hand, a direction of the electrical fault signal received and, on the other hand, a time lag between the time of receipt of the electrical fault signal and the time of receipt of the optical fault signal, and to localize a fault zone from the direction of the electrical fault signal and the time of receipt of the optical and electrical fault signals.

The detection zone may be situated in a segment of the electrical power transmission cable.

The detection zone may be situated at a junction of the electrical power transmission cable.

The winding pitch of the turns of the optical fiber can have a length equal to at least three times the diameter of the insulating jacket on which the optical fiber is wound.

The length of a winding of the optical fiber inside the metal screen can be between 100 and 2000 meters.

A winding of the optical fiber can comprise at least 80 turns.

A plurality of windings of the optical fiber can be disposed on a plurality of segments of the electrical power transmission cable, two successive windings of the optical fiber being separated by a distance of between 10 and 300 kilometers.

It may comprise a first optical fiber with a first plurality of windings, and a second optical fiber with a second plurality of windings, the windings of the first optical fiber being shifted by a predefined distance from the windings of the second optical fiber.

The optical fiber can be a single-mode fiber.

It can comprise a plurality of segments of electrical power transmission cable, two consecutive segments of power transmission cable being connected to each other by junctions, and certain first segments comprising windings between of optical fiber the insulating jacket and the metal screen over their entire length.

In the second segments, the optical fiber can be arranged outside the metal screen.

In the second segments, the optical fiber can be arranged inside the metal screen with a winding pitch at least 10 times greater than for the first segments.

In the second segments, the optical fiber can be arranged inside the metal screen without being wound around the electrically conductive central core, notably with corrugations.

The invention also relates to the associated method for detecting a short-circuit fault in a high-voltage direct-current network, the network comprising at least one detection device such as previously mentioned, the said method comprising the following steps:

transmitting a polarized optical signal between at least a first and a second end of the electrical power transmission cable,

detecting whether the polarization angle of the optical signal transmitted is greater than a predetermined value corresponding to the occurrence of a short-circuit current.

The invention also relates to the method for protecting a high-voltage direct-current network, comprising a detection device such as previously mentioned and the following steps:

transmitting a polarized optical signal between at least a first and a second end of the electrical power transmission cable,

detecting whether the change in the polarization angle of the optical signal transmitted is greater than a predetermined value corresponding to the occurrence of a short-circuit current,

switching the connection of the electrical power transmission cable at the ends if the change in the polarization angle of the transmitted optical signal is greater than a predetermined value.

Other features and advantages of the invention will become apparent from the following description, given by way of example and not of a limiting nature, in relation to the appended drawings in which:

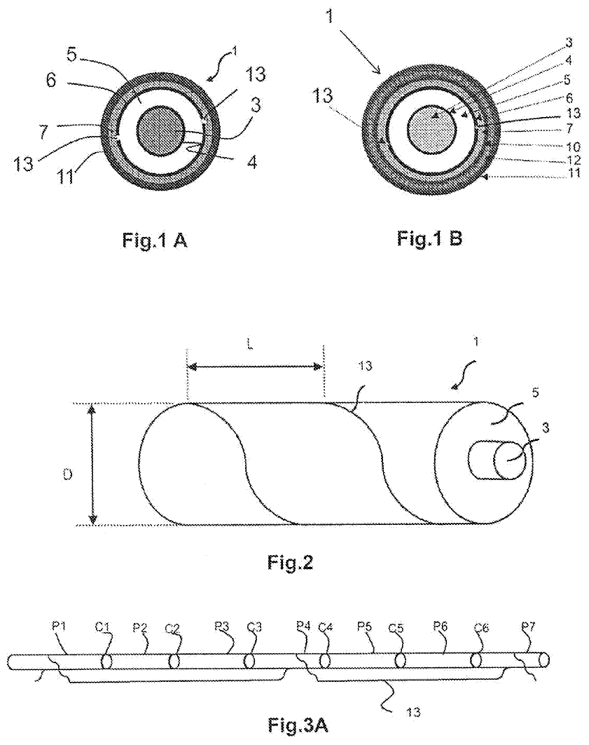

FIG. 1A is a diagram of a section through an electrical power transmission cable according to a first embodiment of the present invention,

FIG. 1B is a diagram of a section through an electrical power transmission cable according to a second embodiment of the present invention,

FIG. 2 is a diagram of an internal part of an electrical power transmission cable according to the present invention,

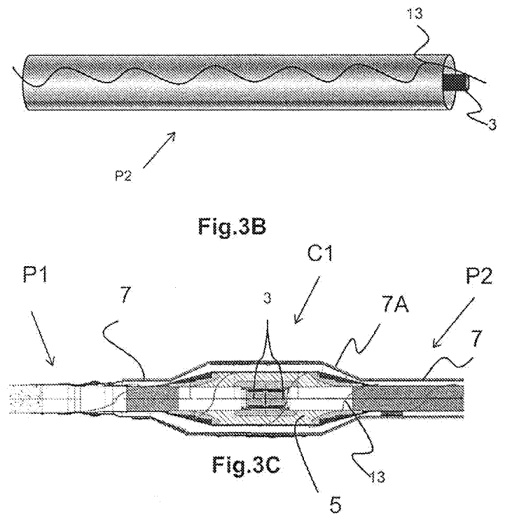

FIG. 3A is a diagram of an electrical power transmission cable comprising various segments,

FIG. 3B shows a cable segment without detection of a short-circuit fault,

FIG. 3C shows an embodiment of a junction for an electrical power transmission cable,

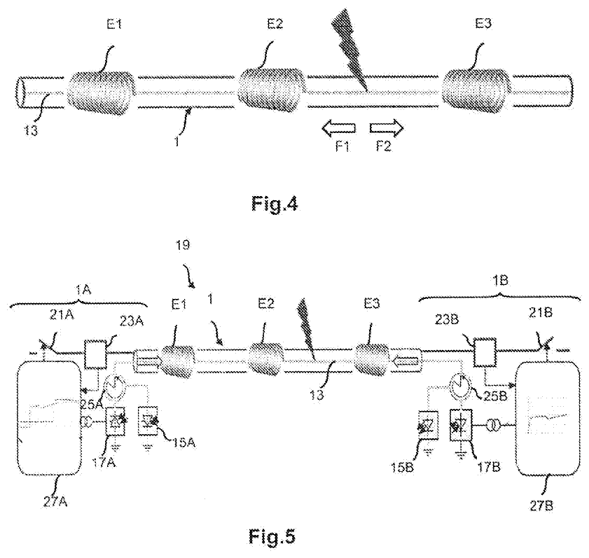

FIG. 4 is a diagram of an electrical power transmission cable and the occurrence of a short circuit in the electrical power transmission cable,

FIG. 5 is a diagram of a detection device and of the signals detected at the ends of a cable during a short circuit,

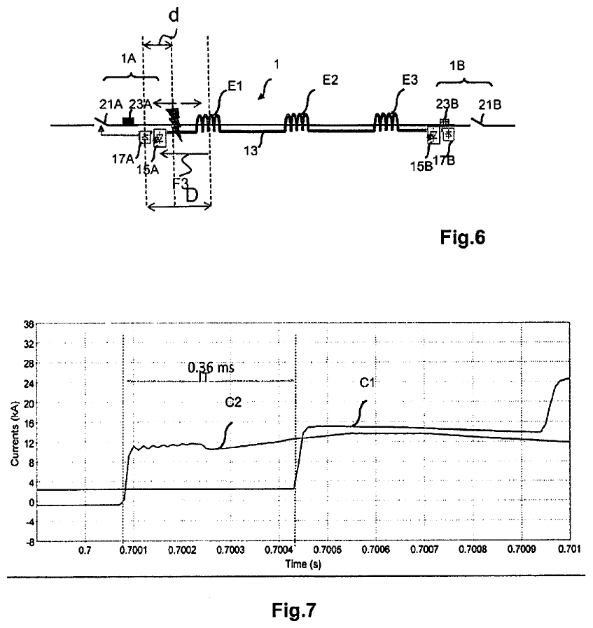

FIG. 6 is a diagram of a detection device with a short circuit at a first location,

FIG. 7 is a graph of the currents measured by an optical detector and a current detector over time in the case of the short circuit in FIG. 6,

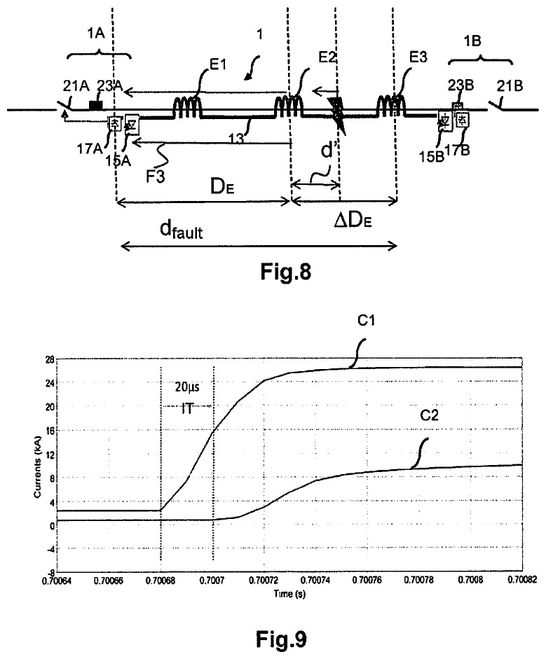

FIG. 8 is a diagram of a detection device with a short circuit in a second location,

FIG. 9 is a graph of the currents measured by an optical detector and a current detector over time in the case of the short circuit in FIG. 8,

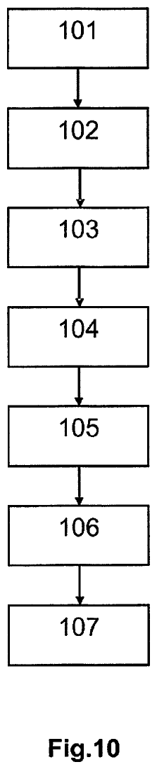

FIG. 10 is a flow chart of the steps in the fault localization method, and

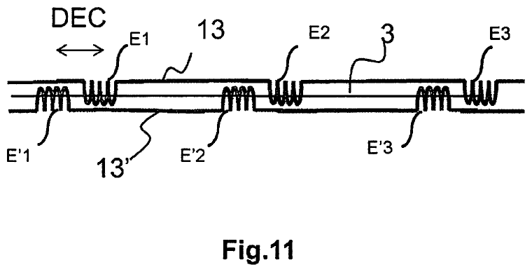

FIG. 11 shows another embodiment with two optical fibers with shifted windings.

In all the figures, elements with identical functions bear the same reference numbers.

The following embodiments are examples. Although the description refers to one or more embodiments, this does not necessarily mean that each reference relates to the same embodiment, or that the features apply only to a single embodiment. Single features of various embodiments can also be combined or exchanged to provide other embodiments.

The terms “upstream” and “downstream” are used to indicate the relative position of elements in the direction of propagation of a short-circuit fault. Thus, a first equipment or element is positioned upstream of a second equipment or element if the short-circuit fault reaches the first equipment first and then the second equipment.

The present invention relates to an electrical power transmission cable intended to be used in a high-voltage direct-current (HVDC) network for the transmission of electrical power, that is to say current.

FIG. 1A is a diagram of a section through an electrical power transmission cable 1 according to a first embodiment of the present invention, and FIG. 2 is a diagram of an internal part of such an electrical power transmission cable 1. This first embodiment can be used for terrestrial networks.

The electrical power transmission cable 1 comprises a central core 3 made of an electrical conductor, for example copper or aluminum, configured to transmit an electrical current. An internal semi-conductive insulation 4 is arranged around the central core. The electrical power transmission cable 1 also comprises an electrically insulating jacket 5, for example made of cross-linked polyethylene or other plastic material, arranged around the conductive core 3 and the internal semi-conductive insulation 4.

An external semi-conductive insulation 6 is arranged around the insulating jacket 5. The electrical power transmission cable 1 also comprises a metal screen 7, also called a sleeve, arranged around the insulating part. This metal screen prevents the emission of the electromagnetic field generated by a current flowing through the central core 3 outside the electrical power transmission cable and also serves to drain the short-circuit current. The metal screen 7 is, for example, made of aluminum or copper or lead, and thus acts as a Faraday cage. Finally, an external protective sheath 11 is arranged around the metal screen 7.

FIG. 1B shows a second embodiment of an electrical power transmission cable 1, which is intended preferentially for an underwater application. This embodiment differs from that in FIG. 1A in particular by the fact that the metal screen 7 in the form of a sleeve is made of lead and that an intermediate layer 10 and a steel metal armor 12 is arranged between the metal screen 7 and the external protective sheath 11.

Furthermore, the electrical power transmission cable 1 comprises at least one optical fiber 13 (two optical fibers 13 are shown in FIGS. 1A and 1B, but a higher number of fibers is also possible) extending along the electrical power transmission cable.

In at least one detection zone of the electrical power transmission cable 1, the optical fiber 13 is arranged between the electrically conductive central core 3 and the metal screen 7 and forms windings around the central core 3.

More specifically, the optical fiber 13 is arranged between the insulating jacket 5 and the metal screen 7, over at least one segment of the electrical power transmission cable 1. In this segment, the optical fiber 13 is wound in the form of turns around the insulating jacket 5. Thus, the optical fiber 13 is exposed to the electromagnetic field emitted by a current flowing through the central core 3, which is not the case for prior-art electrical power transmission cables in which the optical fiber, used for communication or measurement of the temperature of the cable, is arranged outside the metal screen 7, between it and the protective sheath 11. At the locations where the optical fiber 13 is wound around the central core while being arranged below the metal screen 7, a detection zone is thus defined.

Indeed, given that the optical fiber 13 is wound around the insulating jacket 5 and is thus exposed to the electromagnetic field emitted by the central core 3, it is possible to detect a current variation by the use of the Faraday effect where an optical signal crosses the optical fiber 13, this current variation being linked notably to a short-circuit fault in the conductive core 3. This detection based on the Faraday effect will be better described later in the description.

The electrical power transmission cables 1 can be several hundreds of kilometers long depending on electrical power distribution needs. However, for reasons to do with installment of the cables and to cover long distances, electrical power transmission cable segments are used, for example, for terrestrial cables, of a length between 500 m and 2000 m, and typically of 700 m, which segments are placed end to end with the aid of junctions, for example junction boxes or specific cable junctions for underwater cables.

This is schematically shown in FIG. 3A in which the electrical power transmission cable 1 is divided into a plurality of segments labelled P1, P2 . . . P7, and connected to each other by junctions C1, C2 . . . C6 (shown schematically). Certain segments, in the present case the segments P1, P4 and P7, comprise one or more winding(s) of optical fiber 13 inside the cylinder defined by the metal screen 7 (not shown in FIG. 3). The detection zone is situated in a segment and can be formed by a complete segment or by just a portion of a segment.

With regard to the other segments P2, P3, P5 and P6, the optical fiber 13 is arranged such that an optical signal circulating in these segments P2, P3, P5 and P6 is not or is poorly sensitive to the Faraday effect. This is achieved, for example, by arranging the optical fiber 13 outside the metal screen 7 of the same electrical power transmission cable 1, notably in the form of an external optical cable. In the embodiment in FIG. 1A, the optical fiber 13 could be arranged between the metal screen 7 and the protective sheath 11. In the embodiment in FIG. 1B, the optical fiber 13 could be arranged, for example, between the metal screen 7 and the armature 12 of the electrical power transmission cable 1.

In another variant, advantageous notably for underwater cables, the optical fiber 13 is also arranged inside the cylinder defined by the metal screen 7, but with a larger winding pitch, notably a winding pitch that is 10 times larger relative to relative to the segments P1, P4 and P7 such that the fiber 13 of these segments P2, P3 P5 and P6 is very poorly sensitive to the Faraday effect on the optical signals crossing it.

According to yet another variant, in the segments P2, P3, P5 and P6 where no detection of a short-circuit fault is wanted, the optical fiber 13 is arranged inside or outside the metal screen, but without being wound around the electrically conductive central core 3, notably with corrugations on the metal screen 7 or on the insulating jacket 5. This is shown in FIG. 3B for a segment P2. In this case, as there is no complete winding around the conductive central core 3, the Faraday effect cannot affect the optical signal circulating in the optical fiber to modify the polarization of the optical signal.

Furthermore, other optical fibers, not illustrated, for the transmission of optical communication signals can be provided between the metal screen 7 on the one hand, and the external protective sheath 11 of the electrical power transmission cable in the embodiment in FIG. 1A and that in FIG. 1B such that these fibers are not sensitive to the Faraday effect in the event of a short circuit. When a transmission cable 1 is made by segments, the optical fibers 13 for the detection of current faults are, for example, also connected by one segment to another at the junctions C1 to C6. For terrestrial applications, the junctions can be made in junction chambers.

In the variant in FIG. 3A, the windings around the conductive central core 3 can also be situated at a junction, for example C1, C3 or C6.

FIG. 3C shows, by way of example, in a diagrammatic and simplified manner, a junction C1 between two segments P1 and P2 of a, for example underwater, cable.

When the junction C1 is made, following the connection of the conductive central cores 3 of the two segments P1 and P2 to be connected and the placement of an insulating jacket 5 therearound, the optical fiber 13 is wound around the insulating jacket 5 with a defined pitch. The metal screens 7 of the two segments P1 and P2 are connected by a junction body that contains a metal screen 7A and that is positioned in a step following that of winding the optical fiber 13 in such a way that the optical fiber 13 is placed under the metal screen 7A of the junction body. The metal screen 7A of the junction body is finally protected by a heat-shrinkable sheath and other mechanical protection. In this case, the detection zone is situated at a junction, for example C1, C3 or C6.

The optical fibers 13 of the segments P1, P4 and P7 (or alternatively of junctions C1, C3 or C6) can then help to detect current faults by using the Faraday effect.

For this, a winding comprises a given number of turns of optical fibers 13 for each segment P1, P4 and P7 or junction C1, C3 or C6 (for example, 80) so that the Faraday effect is sufficiently large to allow a short-circuit current to be detected.

Furthermore, the optical fibers 13 can be placed in gel-filled tubing to protect the optical fibers 13 from damp, and covered with one or more semi-conductor strips arranged around the optical fibers 13.

The windings of optical fiber 13 can be made with a coil pitch L equal to at least three times, for example four times, the diameter D of the insulating jacket 5 so as to limit torsions of the optical fiber 13 and improve the detection effected by the optical fiber 13, which will be described in greater detail later in the description. The diameter D of the insulating jacket 5 is, for example, 10 cm and the pitch L around 40 cm. Thus, a 700-meter segment P1, P4, P7 of electrical power transmission cable 1 comprises, for example, between 1500 and 1800 turns. Two segments of electrical power transmission cable 1 comprising windings of turns of the optical fiber 13 inside the metal screen 7 are, for example, 10 to 300 km apart. The distance between two windings depends on the desired precision in the localization of a short-circuit fault.

Indeed, the windings of turns around the insulating jacket 5 allow the creation of short-circuit fault detectors integrated in the electrical power transmission cable 1. This detection is based on the Faraday effect which means that the induction created by a current transmitted in a conductor causes the polarization angle of an optical signal transmitted through the optical fiber 13 to turn. The value of this angular shift Δθ of the polarization angle is given by the following equation:

Δθ=V*N*I*cos(α)

where V is the Verdet constant which depends on the optical material in which the optical signal is transmitted (this constant is in the order of 10⁻⁶ rad/A for silica), N is the number of turns of optical fiber 13 around the conductor, I is the value of the current and α is the angle between the plane of the turns and the axis of the conductor, that is the axis of the electrical power transmission cable 1 in the present case. The coil pitch L allows an angle α different from 90°, which would cancel out the angular shift Δθ associated with the Faraday effect, to be obtained.

In practice, the occurrence of a short-circuit fault, for example a short circuit in a section of the electrical power transmission cable 1, causes the appearance of a short-circuit current of a high value, which propagates quickly through the electrical power transmission cable 1 and in both directions.

FIG. 4 shows an example of an electrical power transmission cable 1 comprising three separate windings of optical fiber 13, labelled E1, E2 and E3, and the occurrence of a fault, represented by a lightning flash, in the electrical power transmission cable 1 between the second winding E2 and the third winding E3. The direction of propagation of the short-circuit current is shown by the arrows F1 and F2.

To allow the detection of a fault before its transmission to the ends 1A and 1B of the electrical power transmission cable 1 (see FIG. 5) and thus its propagation to the other equipment in the electrical network, optical transmitters 15A, 15B and optical detectors 17A, 17B are arranged at each end 1A and 1B of the electrical power transmission cable 1 to form, with the electrical power transmission cable 1, a detection device 19.

FIG. 5 is a diagram of a detection device 19. A first optical transmitter 15A and a first optical detector 17A are arranged at a first end 1A of the electrical power transmission cable 1. The first optical transmitter 15A is configured to transmit an optical signal in an optical fiber 13 to the second end 1B of the electrical power transmission cable 1, and a second optical detector 17B associated with the first optical transmitter 15A is arranged at the second end 1B of the electrical power transmission cable 1 to receive the optical signal transmitted by the optical fiber 13.

A second optical transmitter 15B associated with the first optical detector 17A is also arranged at the second end 1B of the electrical power transmission cable 1 and is configured to transmit an optical signal in an optical fiber 13 to the first end 1A of the electrical power transmission cable 1 to be detected by this first optical detector 17A.

The two optical signals can be continuous, pulsed and/or modulated optical signals. They can be transmitted by two separate optical fibers 13 or can be transmitted by the same optical fiber 13 on different wavelengths for a better discrimination or on the same wavelengths given that they propagate in opposite directions. In the case of a single optical fiber 13, the detection device 19 can comprise a first 25A and a second 25B optical circulator. The first optical circulator 25A is situated at a first end of the optical fiber 13 at the first end 1A of the electrical power transmission cable 1 and is configured to transmit the signal from the optical fiber 13 to the first optical detector 17A and to transmit the optical signal from the first optical transmitter 15A to the optical fiber 13.

The second optical circulator 25B is situated at a second end of the optical fiber 13 at the second end 1B of the electrical power transmission cable 1 and is configured to transmit the signal from the optical fiber 13 to the second optical detector 17B and to transmit the optical signal from the second optical transmitter 15B to the optical fiber 13.

Thus, to detect a short-circuit current, optical signals are transmitted in both directions, the value of the polarization angle of the optical signals transmitted, and more precisely the change in the polarization angle, is measured, and when the value of the polarization angle changes by a value greater than a predetermined threshold, the presence of a fault in the electrical power transmission cable 1 is deduced.

The threshold is chosen, on the one hand, depending on the number of windings and the number &turns per winding and, on the other hand, depending on a typical short-circuit current value, for example above 10 kA. Thus, changes in current within a normal operating range of the cable 1 cause small polarization angle changes below the threshold and do not trigger an alert, whereas a short-circuit current exceeding, for example, 10 kA can be easily detected.

For protection reasons, it is not necessary to know precisely the value of the short-circuit current, but simply whether or not it is present.

The detection device 19 also comprises a first switching device 21A arranged at the first end 1A of the electrical power transmission cable 1 and associated with the first optical detector 17A and a second switching device 21B arranged at the second end 1B of the electrical power transmission cable 1 and associated with the second detector 17B.

The switching devices 21A and 21B are configured to allow or not allow the conduction of the current transmitted to and from the electrical power transmission cable 1.

The detection device 19 also comprises a first processing unit 27A situated at the first end 1A of the electrical power transmission cable 1 and configured to process the signals from the first optical detector 17A, and a second processing unit 27B situated at the second end 1B of the electrical power transmission cable 1 and configured to process the signals from the second optical detector 17B. The processing units 27A and 27B are, for example, microcontrollers or microprocessors.

Thus, the optical detectors 17A and 17B and the associated processing units 27A and 27B are configured to detect a shift Δθ of the polarization angle of the optical signal transmitted in the optical fiber 13 greater than a predetermined value, for example a shift of greater than 20°. Indeed, the passage of the short-circuit current through a winding E1, E2, E3 causes a change in the polarization angle Δθ of the optical signal that is detected by the optical detectors 17A and 17B at the ends 1A and 1B of the electrical power transmission cable 1.

FIG. 5 shows schematically, at the first optical detector 17A situated at the first end 1A of the electrical power transmission cable 1, the polarization angle detected as a function of time, with two fronts followed by a plateau, each corresponding to a shift Δθ of the polarization angle of the signal detected. The first front is created by the second winding E2 and the second front is created by the first winding E1 since the two windings E1 and E2 are situated between the position of the fault and the position of the first optical detector 17A (a third front corresponding to the third winding E3 can also be detected after the first two peaks since the short-circuit current propagates in both directions).

At the second optical detector 17B situated at the second end 1B of the electrical power transmission cable 1, a front followed by a plateau created by the third winding E3 is detected (in the same way, two other fronts followed by a plateau corresponding to the windings E2 and E1 can also be detected subsequently—other fronts will follow the first ones due to current waves reflected at the ends of the cable).

Where a shift Δθ of the polarization angle of the signal greater than a predetermined threshold is detected by the first optical detector 17A and the first processing unit 27A, the first processing unit 27A is configured to control open the first switching device 21A to prevent the transmission of the short-circuit current to the other equipment in the network.

In the same way, when a shift Δθ of the polarization angle of the signal greater than a predetermined threshold is detected by the second optical detector 17B and the second processing unit 27B, the second processing unit 27B is configured to control open the second switching device 21B.

Thus, by placing the optical detectors 17A, 17B and the switching devices 21A, 21B at each end 1A, 1B of an electrical power transmission cable 1, it is possible to detect a short-circuit current produced in the electrical power transmission cable 1 and to switch the electrical connection with the rest of the electrical network before the propagation of the short-circuit current to the rest of the electrical network. An electrical power transmission cable can thus be very quickly and effectively isolated from the network where a short-circuit fault arises.

The present invention thus allows the electrical network to be protected by switching the connection of an electrical power transmission cable 1 when a short-circuit current causes a shift of the polarization angle of the optical signal greater than a predetermined threshold.

Moreover, in the event that the optical fiber 13 fails to transmit an optical signal, the processing units 27A and 27B respectively are also configured to control open the switching devices 21A and 21B respectively. Specifically, an absence of a signal can be caused by damage to the electrical power transmission cable 1 such as, for example, a cut or notch in the electrical power transmission cable 1, which can also lead to the formation of a short-circuit current, and hence opening the switching devices 21A, 21B allows the prevention of the transmission of this short-circuit current into the rest of the network.

Additionally, by combining, by means of measures at each end of the electrical power transmission cable 1, the optical detection method described above based on a change in the polarization angle of an optical signal transmitted by the optical fiber 13, with an inductive method for detecting a fault based on the measurement of the current transmitted by the central core 3 at each end, it is possible, by comparing and measuring the detection times for each method, to localize the fault, which allows the activation of the necessary and adequate switching devices to protect the current transmission network.

Indeed, the speed of propagation of the current and notably a short-circuit fault in the electrical power transmission cable 1 is slower than the speed of propagation of the optical signal in the optical fiber 13. For a length of 50 km, the difference in the propagation speeds results in a time lag of 10 μs between the receipt of the optical signal on the one hand, and the arrival of the fault at the same location, on the other hand. Thus, by knowing the direction of propagation of the optical signals and the fault, the location of occurrence of the fault can be localized by measuring this time lag.

For this reason, current detectors 23A, 23B are also placed at each end 1A, 1B, of the electrical power transmission cable 1 to be able to detect directly a current, in particular a short-circuit current transmitted by the electrical power transmission cable 1. These current detectors 23A, 23B can be used to localize the fault in the electrical power supply cable 1. Indeed, the current detectors 23A and 23B allow a transmitted short-circuit current to be detected. A short-circuit current such as this can also be detected by the optical detectors 17A and 17B as previously described. As the optical signals and the short-circuit current move at different speeds, it is possible to determine the distance at which the winding closest to the fault is located, from the detection times of the short-circuit current via the optical detector 17A, 17B and via the current detector 23A, 23B associated with one end of an electrical power transmission cable. The current detector 23A, 23B also allows the direction of propagation of the short-circuit current to be determined, which allows the approximate location of the fault to be deduced, the precision depending on the distance between two windings of optical fiber 13.

Thus, by detecting, at each end of the electrical power transmission cable 1, the occurrence of a fault, on the one hand by an optical detection method based on a change in the polarization angle of an optical signal transmitted by the optical fiber 13, and on the other hand, by an inductive method based on the measurement of the current transmitted by the central core 3, the localization of the fault is possible by taking account of the times of detection of the fault at the ends by the optical detection method on the one hand, and by the inductive detection method on the other hand.

FIG. 10 shows in more detail, a flow chart of an embodiment of various steps in the fault localization method. Certain steps can be optional or reversed.

The method comprises a first step 101 in which an optical signal is transmitted in the optical fiber 13 between the two ends of the electrical power transmission cable 1. The optical signal is transmitted with a known and predefined initial polarization. It may, for example, be a linear polarization with a predefined polarization angle. The wavelength of the optical signal is chosen to be compatible with the optical fiber 13. It may, for example, be a so-called “telecommunication” wavelength in the infrared around 1.5 μm, for example, which minimizes the transmission losses of the optical signal.

The second step 102 is optional and corresponds to the measurement of the polarization angle of the optical signal transmitted by an optical detector 17A, 17B. Indeed, if the polarization of the optical signal is known in advance depending on the light source used, for example a laser diode, this step 102 is not necessary. Alternatively, before coupling the optical signal to the optical fiber 13, the optical signal can be passed into a polarization filter which defines the polarization angle such that, at the filter output, the polarization is clearly defined.

A third step 103 corresponds to the measurement of the current and/or the change in the current transmitted by the central core 3 of the electrical power transmission cable by a current detector 23A, 23B, this being at the ends 1A and 1B of the electrical power transmission cable 1. This measurement can serve, under normal operating conditions, to measure the quantity of current transmitted by the cable and, in the event of a fault, this constitutes an additional means for detecting a short-circuit fault in the electrical power transmission cable 1.

A fourth step 104 relates to the detection of a change in the polarization angle greater than a predetermined threshold by the optical detector 17A, 176 when a fault in the electrical power transmission cable 1 causes the transmission of a short-circuit current.

For this fourth step, it is not necessarily essential to know by an exact measurement, the change in the polarization angle of the transmitted signal, but it is just necessary to detect that a polarization angle has been reached or crossed in order to detect that a fault has occurred in the electrical power transmission cable 1.

Thus, for example, if the polarization angle is at 0° at the input 1A of the electrical power transmission cable 1, and due to the design of the line and the number of turns per winding, a fault is, for example, a change in the current of 10 kA or more, a variation of 10 kA corresponding to a change in the polarization angle of 57°, it is sufficient to place at the second optical detector 17B at the output 1B of the electrical power transmission cable 1, an output polarization filter turned to this value of 57° relative to the input polarization angle of the optical signal.

If a fault occurs, then the second optical detector 17B will be able to measure a light signal when the polarization angle of the light has exceeded 57°. The detection of a signal by the optical detector 17B constitutes, under these conditions, formal proof that a short-circuit fault has occurred.

This corresponds to a fifth step 105 relating to the detection of the short-circuit current transmitted in the central core 3.

A sixth step 106 relates to, for example, the determination of the direction of propagation of the short-circuit current detected. While, as shown in FIG. 4, the short-circuit current propagates in both directions and in opposite current directions as shown by the arrows F1 and F2, it is necessary at, for example, the current detector 23A or the first optical detector 17A to determine whether the fault comes from the electrical power transmission cable 1 or from another electrical power transmission cable to which the electrical power transmission cable monitored is connected within the same transmission network.

The seventh step 107 relates to the localization of the location where the fault occurred, taking account of the detection times of the optical signal presenting a change in the polarization angle characteristic of a short-circuit fault, of the detection of the short-circuit current and of the determined propagation direction.

These various steps can be used for both directions of propagation of the short-circuit fault in the electrical power transmission cable 1 and for a plurality or all of the connection cables 1 in the network in order to quickly localize a fault in the entire network.

FIG. 6 shows an example of a situation where the fault occurs in an end segment, that is: between one end of the electrical power transmission cable 1 and a winding, for example the first end 1A and the first winding E1.

The optical detection method and the inductive method are differentiated between below.

With regard to the optical detection method, for it to work, the short-circuit fault propagating in both directions in the electrical power transmission cable 1 must first reach a winding, and then the optical signal carrying the current fault information by a change in the polarization angle must propagate towards one of the optical detectors 17A, 17B.

In this case, the winding is likely to be the first to detect the short-circuit fault is the winding E1. Then the shortest optical path to reach an optical detector 17A, 17B is indicated by the arrow F3, that is: by the polarized optical signal injected into the optical fiber 13 by the second optical transmitter 15B in the direction of the first optical detector 17A. The first optical detector 17A may thus detect a short-circuit fault corresponding to the transit time from the location of the fault to the winding E1, and then the transit time of the optical signal in the opposite direction of the winding E1 to the first optical detector 17A.

With regard to the inductive detection method based on the current measurement, the current detector 23A may detect the short-circuit fault corresponding to the transit time of the fault in the electrical power transmission cable 1 to the detector 23A.

In both cases, for simplification reasons, the detectors 17A and 23A are assumed to be very fast, notably relative to the front of the optical or electromagnetic signal characteristic of a short-circuit fault.

In this case, it is clear that the short-circuit current arrives at the end 1A of the electrical power transmission cable 1 before the optical fault signal such that it is the current detector 17A which can trigger the opening of the switching device 21A to prevent the propagation of the short-circuit current throughout the network insofar as the short-circuit current does not exceed the tripping capacity of the switching device 21A.

Furthermore, the detection of a fault by the first current detector 23A also triggers the sending of an optical intertripping signal in the direction of the end 1B of the electrical power transmission cable to command the opening of the switch 21B in order to completely isolate the electrical power transmission cable 1. This control signal can be sent by the fiber 13 as a command (for example, by a certain modulation of the optical signal) or by another communication fiber between the ends 1A and 1B and situated outside the metal screen 7 and thus not sensitive to the polarization fault.

Of course, as there is also a polarized optical signal coupled by the transmitter 15A to the optical fiber 13 which propagates from the end 1A to the end 1B, the second optical detector 17B will also detect the short-circuit fault after a time corresponding to the transit time of the short-circuit fault to the winding E1, and then the transit time of the optical signal in the same direction of the winding E1 to the second optical detector 17B.

Finally, at a certain moment, the second current detector 23B will also detect the short-circuit fault after a time corresponding to the transit time of the short-circuit fault from the location of the fault to the second current detector 23B.

In any case, the processing units 27A and 27B are configured to

command open their associated switch 21A or 21B upon receipt of the first received signal of a short-circuit fault, no matter whether it is a signal from a current detector, an optical detector or an optical intertripping signal,

send an intertripping signal to the other end of the electrical power transmission cable 1 if the first received signal of a short-circuit fault is a signal from a current detector or an optical detector.

Moreover, the receipt and the time-domain analysis of the various signals received at the ends 1A and 1B allow the location of the short-circuit fault to be localized. This localization can be approximate, for example to find out between which windings the short-circuit fault occurred, or more precise, for example by measuring the distance between the location where the fault occurred and one of the ends 1A and 1B.

To this end, the first processing unit 27A is also connected to the first current detector 23A and is configured to analyze the chronology of the signals received by the first optical detector 17A and the first current detector 23A and to localize the location of the fault.

Indeed, by determining the direction of the short-circuit current with the aid of the first current detector 23A and the time interval between the moment of detection of the fault from the optical signal and the moment of detection of the fault from the measured current, it is possible to determine approximately the location where the fault has arisen.

For example, FIG. 7 shows an example of a chronological graph of the variation over time of the curves C1 and C2 of the currents detected by the optical detector 17A (curve C1) and by the current detector 23A (curve C2) in the case shown in FIG. 6.

The windings E1, E2, E3 are, for example, placed every 50 kilometers. The propagation time of the current over 50 kilometers is, for example, 0.26 ms whereas the propagation time of the optical signal over 50 kilometers is 0.25 ms. Thus, if the fault is situated at 15 kilometers from the first end 1A of the electrical power transmission cable 1, the short-circuit current will be detected by the current detector at around 75 μs after its occurrence.

The detection of the short-circuit current by the optical detector occurs at 442 μs (30 km transit of the short-circuit fault to E1, then 50 km transit from E1 to the first end 1A).

There is thus a difference or TI lag of 367 μs.

Thus, knowing that: the short-circuit fault signal measured by the current detector 23A was received before the short-circuit fault signal measured by the optical detector 17A and taking account of the time lag in receiving the signals, it is possible to localize the location of the fault.

As the signal the short-circuit fault signal measured by the current detector 23A was received before the short-circuit fault signal measured by the optical detector 17A, the fault must have occurred in a portion of the electrical power transmission cable 1 situated between one end and a first winding.

In this case,

$$d = \frac{1}{2} ( D - {v}_{CD} ( Δ {t}_{ext} - \frac{D}{{v}_{opt}} )$$

where:

d is the distance between the end and the location where the short-circuit fault occurred,

D is the distance between the end of the electrical power transmission cable and the first winding for the optical detection,

v_{CD} is the speed of propagation of the short-circuit fault in the electrical power transmission cable 1,

vₒₚₜ is the speed of propagation of an optical signal in the optical fiber 13,

Δtₑₓₜ is the lag measured between the time of detection of the short-circuit fault by optical detection and the time of detection of the short-circuit fault by current measurement, the latter occurring before the time of detection of the short-circuit fault by optical detection.

If the fault occurs 135 kilometers from the first end 1A as shown in FIG. 8, the fault is detected by the optical signal 20 μs before the arrival of the short-circuit current, as indicated in the graph in FIG. 9, which allows, on the one hand, the first switching device 21A to be opened to prevent the propagation of the short-circuit current and, on the other hand, the location of the fault to be determined from this time lag of 20 μs and from the direction of arrival of the current signal coming from the electrical power transmission cable 1.

More precisely, the time lag and the analysis of the chronology of the signals allows the detection of the winding which first detected the short-circuit fault, and of the distance of this winding from the end.

In this case,

$${D}_{E} = ( Δ t * \frac{{v}_{opt} {v}_{CD}}{{v}_{CD} - {v}_{opt}} )$$

where:

D_{E} is the distance between the end and the location where the winding was first crossed by the short-circuit fault which occurred,

v_{CD} is the speed of propagation of the short-circuit fault in the electrical power transmission cable 1,

vₒₚₜ is the speed of propagation of an optical signal in the optical fiber 13,

Δt is the time lag measured between the time of detection of the short-circuit fault by optical detection and the time of detection of the short-circuit fault by current measurement, the latter occurring after the time of detection of the short-circuit fault by optical detection.

This allows the localization of the winding at which the short-circuit fault was able to be detected first (here E2 by looking at the propagation of the optical signals from the end 1B to the end 1A).

To determine more precisely the location where the short-circuit fault occurred, it is possible to use the signals detected at the other end of the cable and/or the optical signals produced by the other windings of optical fiber.

This, the short-circuit fault propagates in both directions in the power transmission cable. It will thus also produce a change in the polarization of the optical signal, which can be detected by the first optical detector 17A.

If t₁ is the time between the occurrence of the electrical fault and the time of detection of the short-circuit fault by optical detection, when the change in polarization is generated by the winding E2:

$${t}_{1} = ( \frac{{d}^{′}}{{v}_{CD}} + \frac{{D}_{E}}{{v}_{opt}} )$$

the fault occurred between two windings and d′ is the distance between the location where the short-circuit fault occurred and the proximal winding, that is the winding which is closest to the optical detector measuring the polarization change.

If t₃ is the time between the occurrence of the electrical fault and the time of detection of the short-circuit fault by optical detection, when the polarization change is generated by the winding E3:

$${t}_{3} = ( \frac{Δ {D}_{E} - {d}^{′}}{{v}_{CD}} + \frac{{D}_{E} + Δ {D}_{E}}{{v}_{opt}} )$$

where ΔD_{E} is the distance between the two windings, here E2 and E3, between which the short-circuit occurred.

In this case,

$${d}^{′} = \frac{1}{2} ( Δ {D}_{E} \frac{{v}_{opt} + {v}_{CD}}{{v}_{opt}} - Δ {t}^{′} {v}_{CD} )$$

with Δt′=t₃−t₁

It can thus be determined with precision that the short-circuit fault occurred at a distance d_{fault}=D_{E}+d′ from the first optical detector 17A arranged at the first end 1A.

By similar reasoning, the distance of the fault from the second end can also be calculated and thus the result consolidated.

It is apparent that the localization can be carried out by using only the optical signals.

The localization of the location also helps facilitate repair operations on the electrical power transmission cable 1.

In the event of a short-circuit current arriving in the opposite direction, the distance of the fault in an adjacent electrical power transmission cable 1 can be detected.

Thus, the use of a detection device 19 such as previously described allows the detection of a short-circuit current propagating in an electrical power transmission cable 1 of a high-voltage direct-current network and the limitation of the propagation of the short-circuit current in the rest of the network by opening the switching devices 21A and 21B arranged at the ends of the electrical power transmission cable 1, ensuring the protection of equipment in the network even when the short-circuit current is of a magnitude above 20 kA.

Moreover, a detection device 19 such as this can be used in combination with the use of inductances arranged at the ends of the connection cables 1 to limit the amplitude of the short-circuit current since the short-circuit current is detected in the windings of optical fiber 13 and not at the ends of the electrical power transmission cable 1.

Finally, the identification of a short-circuit fault by the optical method is much easier as the change in the current inside the cable, very close to the short-circuit fault, is greater than the change in current that can be measured at the ends of the electrical power transmission cable 1, notably by via inductances at the ends.

According to yet another development shown in FIG. 11 in a simplified manner with just the conductive central core 3, the electrical power transmission cable 1 is fitted with a first fiber 13 with a first plurality of windings E1, E2 and E3, each defining a detection zone and a second fiber 13′ with a second plurality of windings E′1, E′2 and E′3, each also defining a detection zone. Of course, each optical fiber 13, 13′ is fitted at its ends with transmitters and receivers as described above but which are not shown in FIG. 11. The windings E1, E2 and E3 of the first fiber 13 are shifted by a distance DEC from the windings E′1, E′2 and E′3 of the second optical fiber 13′. This further improves the reliability of the short-circuit current fault detection.

1. A device (19) for detecting a short-circuit current in an electrical power transmission cable (1), comprising:
an electrical power transmission cable (1) for a high-voltage direct-current network, comprising:
an electrically conductive central core (3) configured to transmit an electrical current,
an electrically insulating jacket (5) arranged around the central core (3),
a metal screen (7) arranged around the insulating jacket (5),
and wherein the electrical power transmission cable (1) also comprises at least one optical fiber (13) extending along the electrical power transmission cable, in which cable, in at least one detection zone of the electrical power transmission cable (1), the said optical fiber (13) is arranged between the electrically conductive central core (3) and the metal screen (7) and forms windings around the central core (3),
a first optical transmitter (15A) arranged at a first end (1A) of the electrical power transmission cable (1) and configured to transmit an optical signal in an optical fiber (13) of the said electrical power transmission cable (1),
a second optical transmitter (15B) arranged at a second end (1B) of the electrical power transmission cable (1) and configured to transmit an optical signal in an optical fiber (13) of the said electrical power transmission cable (1),
a first optical detector (17A) arranged at the first end (1A) of the electrical power transmission cable (1) and configured to detect a change in the polarization angle of the optical signal transmitted by the second optical transmitter (15B) and associated with a fault signal,
a first switching device (21A) arranged at the first end (1A) of the electrical power transmission cable, coupled to the first optical detector (17A) and configured to switch the connection of the electrical power transmission cable (1) when a change in the polarization angle, relative to a reference angle, greater than a predetermined value is detected by the first optical detector (17A),
a second optical detector (17B) arranged at the second end (1B) of the electrical power transmission cable (1) and configured to detect a change in the polarization angle of the optical signal transmitted by the first optical transmitter (15A) and associated with a fault signal,
a second switching device (21B) arranged at the second end (1B) of the electrical power transmission cable (1), coupled to the second optical detector (17B) and configured to switch the connection of the electrical power transmission cable (1) when a change in the polarization angle, relative to a reference angle, greater than a predetermined value is detected by the second optical detector (17B).

2. The detection device (19) as claimed in claim 1, wherein the first (21A) or the second (21B) switching device respectively is also configured to switch the connection of the electrical power transmission cable in the absence of receipt of an optical signal by the first optical detector (17A) or by the second optical detector (17B) respectively.

3. The detection device (19) as claimed in claim 1, wherein the first optical transmitter (15A) is configured to transmit a signal at a first wavelength, and the second optical transmitter (15B) is configured to transmit a signal at a second wavelength different from the first wavelength.

4. The detection device (19) as claimed in claim 1, also comprising:
a first current detector (23A) arranged at the first end (1A) of the electrical power transmission cable (1) and configured to detect an electrical fault signal transmitted by the electrical power transmission cable (1),
a first processing unit (27A) arranged at the first end (1A) of the electrical power transmission cable (1) and coupled to the first optical detector (17A) and to the first current detector (23A), and configured to determine, on the one hand, a direction of the electrical fault signal received and, on the other hand, a time lag between the time of receipt of the electrical fault signal and the time of receipt of the optical fault signal, and to localize a fault zone from the direction of the electrical fault signal and the time of receipt of the optical and electrical fault signals,
a second current detector (23B) arranged at the second end (1B) of the electrical power transmission cable (1) and configured to detect an electrical fault signal transmitted by the electrical power transmission cable (1),
a second processing unit (27B) arranged at the second end (1B) of the electrical power transmission cable (1) and coupled to the second optical detector (17B) and to the second current detector (23B), and configured to determine, on the one hand, a direction of the electrical fault signal received and, on the other hand, a time lag between the time of receipt of the electrical fault signal and the time of receipt of the optical fault signal, and to localize a fault zone from the direction of the electrical fault signal and the time of receipt of the optical and electrical fault signals.

5. The detection device as claimed in claim 1, wherein the detection zone is situated in a segment (P1, P4, P7) of the electrical power transmission cable (1).

6. The detection device as claimed in claim 1, wherein the detection zone is situated at a junction (C1, C3, C6) of the electrical power transmission cable (1).

7. The detection device as claimed in claim 1, wherein the winding pitch of the turns of the optical fiber (13) has a length equal to at least three times the diameter (D) of the insulating jacket (5) on which the optical fiber (13) is wound.

8. The detection device as claimed in slain% claim 1, wherein the length of a winding (E1, E2, E3) of the optical fiber (13) inside the metal screen (7) is between 100 and 2000 meters.

9. The detection device as claimed in claim 1, wherein a winding (E1, E2, E3) of the optical fiber (13) comprises at least 80 turns.

10. The detection device as claimed in claim 1, wherein a plurality of windings (E1, E2, E3) of the optical fiber (13) is disposed on a plurality of segments of the electrical power transmission cable (1), two successive windings (E1, E2, E3) of the optical fiber (13) being separated by a distance of between 10 and 300 kilometers.

11. The detection device as claimed in claim 1, wherein it comprises a first optical fiber with a first plurality of windings (E1, E2, E3), and a second optical fiber with a second plurality of windings (E1, E2, E3), the windings of the first optical fiber being shifted by a predefined distance from the windings of the second optical fiber.

12. The detection device as claimed in claim 1, wherein the optical fiber (13) is a single-mode fiber.

13. The detection device as claimed in claim 1, comprising a plurality of segments (P1, P2 . . . P7) of electrical power transmission cable, two consecutive segments of power transmission cable (1) being connected to each other by junctions, and wherein certain first segments (P1, P4, P7) comprise windings (E1, E2, E3) of optical fiber (13) between the insulating jacket (5) and the metal screen (7) over their entire length.

14. The detection device as claimed in claim 13, wherein, in the second segments (P2, P3, P5, P6), the optical fiber (13) is arranged outside the metal screen (7).

15. The detection device as claimed in claim 13, wherein, in the second segments (P2, P3, P5, P6), the optical fiber (13) is arranged inside the metal screen (7) with a winding pitch at least 10 times greater than for the first segments (P1, P4, P7).

16. The detection device as claimed in claim 13, wherein, in the second segments (P2, P3, P5, P6), the optical fiber (13) is arranged inside the metal screen (7) without being wound around the electrically conductive central core (3), notably with corrugations.

17. A method for detecting a short-circuit fault in a high-voltage direct-current network, the network comprising at least one detection device (19) as claimed in claim 1, the said method comprising the following steps:
transmitting a polarized optical signal between at least a first and a second end of the electrical power transmission cable (1),
detecting whether the polarization angle of the optical signal transmitted is greater than a predetermined value corresponding to the occurrence of a short-circuit current.

18. The method for protecting a high-voltage direct-current network, the network comprising at least one detection device (19) as claimed in claim 1, the said method comprising the following steps:
transmitting a polarized optical signal between at least a first and a second end of the electrical power transmission cable (1),
detecting whether the change in the polarization angle of the optical signal transmitted is greater than a predetermined value corresponding to the occurrence of a short-circuit current,
switching the connection of the electrical power transmission cable (1) at the ends (1A, 1B) if the change in the polarization angle of the transmitted optical signal is greater than a predetermined value
